(19) United States
(12) Patent Application Publication
(10) Pub. No.: US 2026/0026140 A1
(43) Pub. Date: Jan. 22, 2026

(54) MONOLITHIC LED ARRAY AND METHOD OF MANUFACTURING OF THEREOF

(71) Applicant: Lumileds LLC, San Jose, CA (US)

(72) Inventors: Grigoriy Basin, San Francisco, CA (US); Mikhail Fouksman, Emerald Hills, CA (US); Norbert Lesch, Vaals (NL); Benno Spinger, Aachen (DE)

(73) Assignee: Lumileds LLC, San Jose (CA)

(21) Appl. No.: 18/775,358

(22) Filed: Jul. 17, 2024

(51) Int. Cl. H01L 33/50; H01L 25/075; H01L 33/00; H01L 33/46; H01L 33/56; H01L 33/62

(52) U.S. Cl. CPC H10H 20/8511; H01L 25/0753; H10H 20/01; H10H 20/018; H10H 20/841; H10H 20/854; H10H 20/857; H10H 20/034; H10H 20/0361; H10H 20/0362

(57) ABSTRACT

Described is a light emitting diode (LED) array comprising: a plurality of phosphor-converted light-emitting diodes (PC-LEDs) arranged in a grid on a solid tile support, a reflective coating surrounding PC-LEDs in place, each of the PC-LEDs comprising: a die including an under bump metallization (UBM) affixing the PC-LED to a surface of the solid tile support; a phosphor layer affixed to a surface of the die opposite the UBM, and a transparent cover layer on the phosphor layer.

### TECHNICAL FIELD

Embodiments of the disclosure generally relate to light emitting devices and methods of manufacturing the same. More particularly, embodiments are directed to a light emitting diode (LED) array that includes light-emitting diodes including a phosphor layer and a transparent cover layer thereon (phosphor-converted light-emitting diodes (PC-LEDs)) arranged in a grid surrounded by a reflective coating, which includes a channel filled with a light absorbing material, on a solid tile support.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate, e.g., a growth substrate, formed of for example sapphire or silicon carbide (SiC).

For LED arrays used in high brightness applications, side light emission from LEDs is blocked by highly reflective coating. Thickness of reflective side coating and accuracy of LED placement processes generally result in distances of on the order of 500 μm to 600 μm between light emitting areas. Large distances between light emitting areas causes highly visible dark lines in the projected light beam, however, which interferes with application of the LED array. Additionally, rotational accuracy of LED placement can cause distortion of the projected beam and can reduce maximum intensity of the projected light beam.

Some LED placement processes include attaching LEDs onto a flexible support material such as tape, and thereafter processing to prepare a grid of LEDs having a reflective coating material around each of the LEDs and optionally a light absorbing material in openings in the reflective coating material. The support material such as tape is thereafter removed to form an LED array. Handling a plurality of LEDs on a flexible support material such as tape, however, can lead to manufacturing inefficiencies and loss of yield.

There is a need for improved handling and yield of light emitting diode (LED) arrays with minimal dark gaps between light emitting areas.

### SUMMARY

Embodiments of the disclosure are directed to monolithic light-emitting diode (LED) arrays, and systems including the LED arrays, and methods of making and using the LED arrays.

In an aspect, a light emitting diode (LED) array comprises: a plurality of phosphor-converted light emitting diodes (PC-LEDs) arranged in a grid on a solid tile support, a reflective coating surrounding each of the PC-LEDs in place, each of the PC-LEDs comprising: a die including an under bump metallization (UBM) affixing the PC-LED to a surface of the solid tile support; a phosphor layer affixed to a surface of the die opposite the UBM, and a transparent cover layer on the phosphor layer.

Another aspect includes a headlamp module comprising any LED array herein, and a headlamp lens configured to receive light from the LED array.

An additional aspect is a method of manufacturing a light-emitting diode (LED) array, the method comprising: attaching a plurality of phosphor-converted light-emitting diodes (PC-LEDs) including a transparent cover layer in a spaced apart configuration to a solid tile support; depositing a reflective material around the PC-LEDs; preparing a channel in the reflective material between the PC-LEDs; filling the channel with a light absorbing material; and planarizing by removing a thin layer of the reflective material, the light absorbing material, and the transparent cover layer to form a light-emitting diode (LED) array.

A further aspect is method of manufacturing a light-emitting diode (LED) array, the method comprising: attaching a plurality of light-emitting diode (LED) die in a spaced apart configuration to a solid tile support; depositing a first reflective material around the LED die; removing a portion of the first reflective material to expose a growth substrate of each of the LED die; removing the growth substrate of each of the LED die; attaching a phosphor layer to each of the LED die, and a transparent cover layer on the phosphor layer to prepare phosphor-converted light-emitting diodes (PC-LEDs); disposing a second reflective material around the PC-LEDs; preparing a channel in the second and optionally first reflective materials between each of the PC-LEDs; filling the channel with a light absorbing material; and planarizing by removing a thin layer of the second and optionally first reflective materials, the light absorbing material, and the transparent cover layer to form a light-emitting diode (LED) array.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements.

FIGS. 1-2 illustrate process flow diagrams for methods herein;

FIG. 3 illustrates a cross-sectional view of a phosphor-converted light emitting diode (PC-LED) according to one or more embodiments;

FIGS. 4-9 illustrate cross-sectional views of a light emitting device (interim structure and/or array) after various operations in the manufacture according to one or more embodiments;

FIG. 10 illustrates cross-sectional view of an LED device according to one or more embodiments;

FIG. 11 illustrates a top plan view of the LED device of FIG. 10 according to one or more embodiments;

FIG. 12 illustrates cross-sectional view of an LED device according to one or more embodiments;

FIG. 13 illustrates a top plan view of the LED device of FIG. 12 according to one or more embodiments;

FIG. 14 illustrates a cross-sectional view of a die according to one or more embodiments;

FIGS. 15-23 illustrate cross-sectional views of a light emitting device (interim structure and/or array) after various operations in the manufacture according to one or more embodiments;

FIGS. 24-26 illustrate top plan views of various LED arrays according to one or more embodiments;

FIG. 27 shows a cross-section side view of a headlamp module according to one or more embodiments; and

FIG. 28 shows a block diagram of an LED system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “monolithic light emitting diode (LED) array” refers to a multitude of LED die or chips rigidly mounted to a device substrate. Emitters are arranged in an X, Y addressable matrix and may have separately addressable connection. The spacing between light emitting areas can vary in size according to the application. The array sizes and shapes can vary to meet specific requirements.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

The term “wafer” and “substrate” will be used interchangeably in the instant disclosure. Thus, as used herein, a wafer serves as the substrate for the formation of the LED devices described herein. A growth or monolithic substrate is a substrate on which semiconductor layers are formed.

A device substrate is a substrate to which a LED chip or die or array is transferred and/or affixed after the semiconductor layers are formed. Exemplary device substrates are: circuit boards, tiles, metalized ceramics, thin film display backplane, CMOS backplane, CMOS microIC, and/or the like. These device substrates range in use from support or sub-mounts for individual LEDs or pixels to fully integrated electronics for displays and lighting applications and other suitable devices or systems.

As used herein, reference to the plurality of LED die being spaced apart and retained or fixed or held in place by a reflective coating means that an array of such LED die is self-supporting in that the array can be handled and processed without residing on a support. Such self-supporting arrays can be planarized and subsequently bonded and electrically coupled to a backplane, PCB, submount, and the like.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, LED fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Embodiments described herein provide a monolithic array of PC-LEDs on a solid tile support. In one or more embodiments, the monolithic array of PC-LEDs is attached to each other by a highly reflective coating. Such a monolithic device later can be later mounted to an appropriate printed circuit board (PCB) or other substrate. In one or more embodiments, to control light cross talk between the PC-LEDs, a light absorbing material is inserted in channels of the reflective coating.

As to the solid tile support, advantageously, the PC-LEDs are positioned on such an inflexible material for processing arrays, which is included in a final device. By eliminating transfer to and from a flexible support, for example tape, in favor of a solid tile support, manufacturing efficiencies and yield can be improved. For example, pick-and-place techniques would not be needed for arrays processed on solid tile supports. In addition, more PC-LEDs are able to be assembled onto the solid tile support as compared to the flexible support. Also, placement accuracies are improved for arrays processed on solid tile supports. As related specifically to PC-LEDs, which include a phosphor layer and a transparent cover layer on a die, the PC-LEDs are placed UBM-side down on the solid tile support and processed thereafter with reflective and optionally light absorbing materials, and at least a portion of the transparent cover layer may be sacrificed later during planarization while protecting the phosphor layer. As to the phosphor layers, which in some embodiments are wider than an underlying semiconductor-containing structure, use of adhesive filets spanning from undersides of the phosphor layers to side surfaces of the respective die improves efficiency.

In some embodiments, configuring the following optical distances enhances light extraction: d1, (first) distance between the phosphor layers; d2, (second) distance between semiconductor-containing structures; and d3 thickness of light absorbing material. In one or more embodiments, d1 is in a range of greater than or equal to 10 μm to less than or equal to 1000 μm, including greater than or equal to 50 μm to less than or equal to 100 μm; and/or d2 is in a range of greater than or equal to 10 μm to less than or equal to 1000 μm, including greater than or equal to 120 μm to less than or equal to 500 μm; and/or d3 is in a range of greater than or equal to 1 μm to less than or equal to 1000 μm, including greater than or equal to 20 μm to less than or equal to 50 μm.

Herein, embodiments include light-emitting diode (LED) arrays comprising: a plurality of phosphor-converted light emitting diodes (PC-LEDs) arranged in a grid on a solid tile support; a reflective coating surrounding each of the PC-LEDs in place, each of the PC-LEDs comprising: a die including an under bump metallization (UBM) affixing the PC-LED to a surface of the solid tile support; a phosphor layer affixed to a surface of the die opposite the UBM, and a transparent cover layer on the phosphor layer. In one or more embodiments, the reflective coating retains the PC-LEDs in place on the solid tile support.

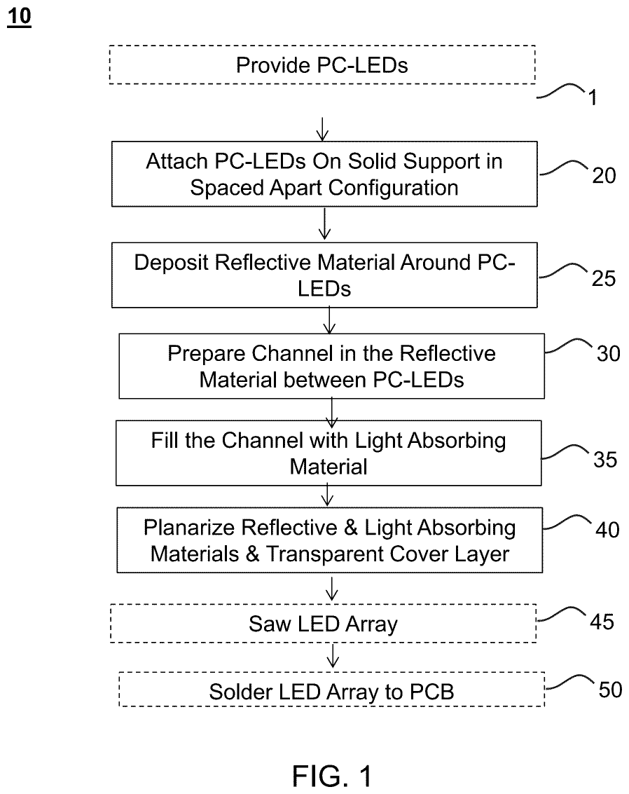

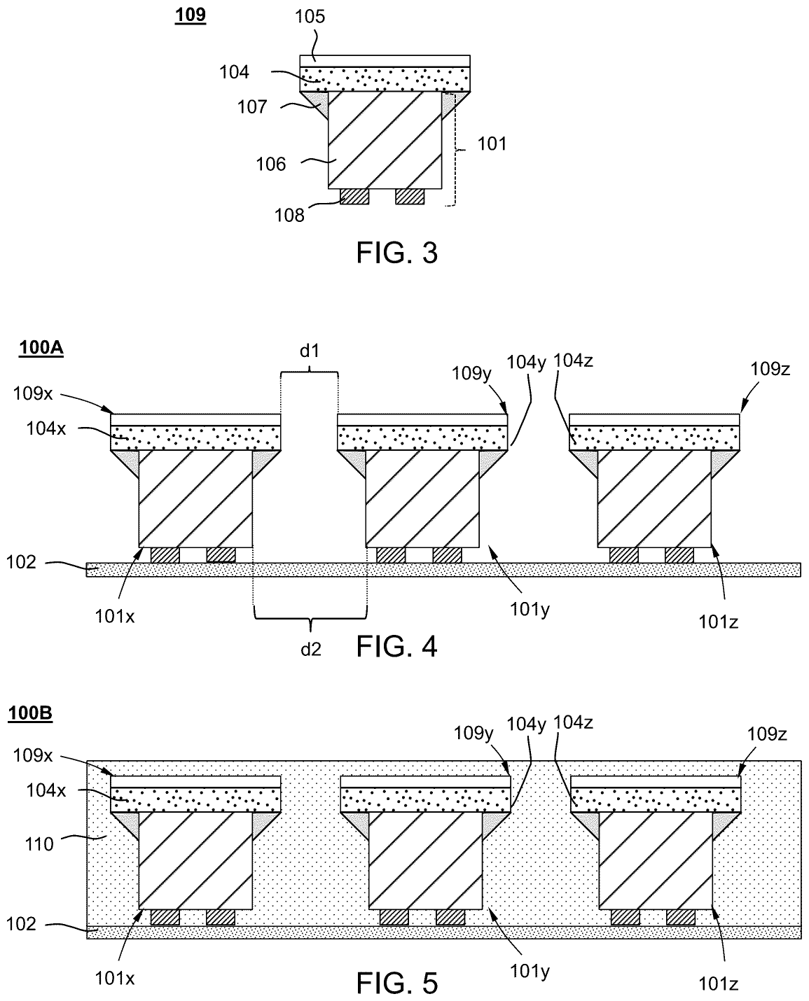

The following is with reference to FIG. 1 and FIGS. 3-13. FIGS. 4 to 13 illustrate views of LED intermediate structures/arrays 100A to 100F during preparation of an LED device 200 following the process flow illustrated for method 10 of FIG. 1.

FIG. 1 depicts a flow diagram of a method 10 of manufacturing a light emitting device in accordance with one or more embodiments of the present disclosure. With reference to FIG. 1, in one or more embodiments, the method begins at operation 1 where phosphor-converted light emitting diodes (PC-LEDs) are provided. As used in this specification and the appended claims, the term “provided” means that the PC-LEDs are made available for processing.

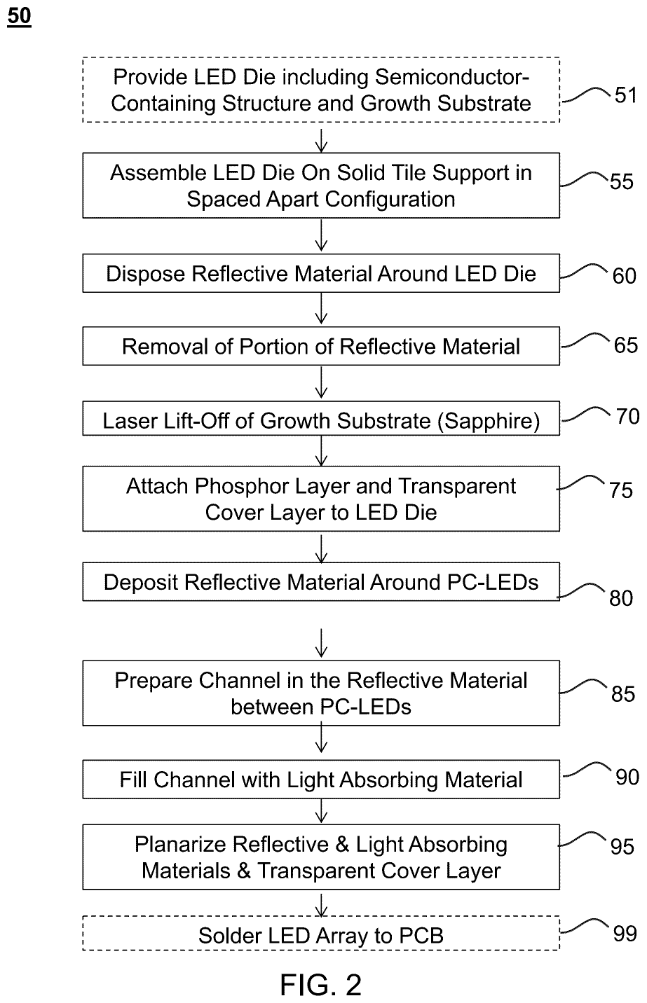

FIG. 3 illustrates a cross-sectional view of a phosphor-converted light emitting diode (PC-LED) 109 according to one or more embodiments.

The PC-LED 109 comprises an underlying LED die 101, a phosphor layer 104 affixed to the LED die 101, and a transparent cover layer 105 on the phosphor layer 104. The LED die 101 comprises a semiconductor-containing structure 106 and at least one electrical contact, otherwise known as an underbump metallization (UBM) 108. For illustration purposes, two UBMs 108 are shown in FIG. 3. Reference to “semiconductor-containing structure” means at least a stack of semiconductor layers, with or without a growth substrate, with or without internal bonding layers or other layers/features. The phosphor layer 104 is affixed to the semiconductor-containing structure 106 by an adhesive, which includes adhesive filets 107, which add to structural integrity of the PC-LED 109. In one or more embodiments, the phosphor layer has a width greater than a width of the die to which it is affixed. Width of the die is considered by its widest point. For example, the widest point of the LED die 101 is a semiconductor-containing structure 106. In one or more embodiments, the adhesive filet spans from an underside of the phosphor layer to side surfaces of the respective semiconductor-containing structure. For illustration purposes, the PC-LED 109 has a flip chip configuration. In one or more embodiments, the flip chip configuration is a thin film flip chip configuration (TFFC). In one or more embodiments, the vertical flip chip structure optionally includes a silicon substrate.

As used herein, the term “phosphor” refers to a solid material which emits visible light when exposed to radiation from a deep blue, ultra-violet, or electron beam source. Through careful tuning of the phosphor composition and structure, the spectral content of the emitted light can be tailored to meet certain performance criteria. In some embodiments, the phosphor layer may be a ceramic phosphor, a phosphor in glass, or a platelet of phosphor in silicone. In one or more embodiments, the phosphor layer is a ceramic phosphor comprising a polycrystalline ceramic plate of a phosphor material, optionally comprising: a Ce(III)-doped garnet material ((M^{I}_{1-x-y}M^{II}ₓM^{III}_{y})₃(Al_{1-z}M^{IV}_{Z})₅O₁₂ with M^{I}=(Y, Lu); M^{II}=(Gd, La, Yb); M^{III}=(Tb, Pr, Ce, Er, Nd, Eu) and M^{IV}=(Gd, Sc) with 0<x<I; 0<y≤I; and 0<z<1), or a Ce(III) and/or Eu(II) doped nitridosilicate (M₂Si₅N₈), or an oxonitridosilicate material (MSi₂O₂N₂) (M=alkaline earth)).

In some embodiments, the transparent cover layer comprises a glass; a sapphire; or a silicone material, optionally the silicone material further including titania (TiO₂) and/or silica (SiO₂).

The UBM 108 may comprise any suitable contact known to the skilled artisan. For example, in some embodiments, the UBM 108 may comprise one or more of a p-type contact or an n-type contact. In some embodiments, the UBM 108 includes a metal selected from one or more of copper (Cu), nickel (Ni), aluminum (AI), and gold (Au). In one or more embodiments, the UBMs herein are plated with gold (Au) through an immersion process to form gold plated electrical contacts. Gold (Au) plating is done by electroless nickel immersion gold (ENIG). It comprises electroless nickel plating, which is covered with a thin layer of immersion gold. In immersion gold, the gold layer is generated on the nickel layer through displacement. It continues until the generated gold layer is covered with nickel. This is why gold layer is very thin. This layer protects nickel from oxidation.

At operation 20 of FIG. 1, the PC-LEDs are assembled on a solid tile support in a spaced apart configuration. Solid tile supports include but are not limited to: an interposer, a printed circuit board (PCB), or a ceramic substrate. Assembling the PC-LEDs on the solid tile support at operation 20 of FIG. 1 yields intermediate LED structure 100A of FIG. 4, which comprises a plurality of PC-LEDs 109x, 109y, and 109z, which include respective features analogous to FIG. 3: phosphor layers 104x, 104y, 104z affixed to respective LED die 101x, 101y, 101z (which each include semiconductor-containing structure and UBM and adhesive filet), and transparent cover layers 105x, 105y, 105z on the respective phosphor layers 104x, 104y, 104z.

The PC-LEDs 109x, 109y, and 109z are assembled onto a surface of the solid tile support 102 by way of their respective UBMs. Distance “d1” is between adjacent phosphor layers 104x, 104y, 104z. In one or more embodiments, d1 is in a range of from 50 μm to 100 μm. Distance “d2” is between adjacent underlying die 101x, 101y, 101z, as measured at the widest point. It is understood that an entire assembly of the various PC-LEDs 109x, 109y, and 109z from total number to arrangement of grids is done according to end-applications.

In one or more embodiments, the solid tile support 102 comprises any suitable support material that is inflexible, meaning the support can transport assembled die and any resulting array without flexing or bending. In one or more embodiments, the solid tile support 102 is an interposer, a printed circuit board (PCB), or a ceramic substrate.

Turning to FIG. 5 and intermediate structure 100B, at operation 25 of method 10, a reflective material 110 is disposed around the PC-LEDs of the intermediate structure 100A. In one or more embodiments, the reflective material 110 is molded around the PC-LEDs. The reflective material 110 interacts with all surfaces of the PC-LEDs 109x, 109y, and 109z except for the UBM surfaces that are on the solid tile support 102.

In one or more embodiments, the reflective material 110 is highly reflective having a reflectance in a range of from 80% to 99%, including all values and subranges therebetween, including in a range of from 80% to 98%, or in a range of from 90% to 98%, or in a range of from 91% to 97%, or in a range of from 92% to 96%, or in a range of from 93% to 95%.

The reflective material 110 may comprise any suitable material known to the skilled artisan. In one or more embodiments, the reflective material is selected from one or more of silicone, titanium oxide (TiO₂), zirconium oxide (ZrO₂), aluminum oxide (Al₂O₃), or other metal oxides.

At operation 30, a channel is prepared in the reflective material 110 between the PC-LED. As shown in FIG. 6 and intermediate structure 100C, channels 112 extend into the reflective material 110 to a desired depth towards the solid tile support 102. The channel extends at least partially into the reflective material. In some instances, as illustrated, the channel 112 extends completely through the reflective material 110 to the solid tile support 102. The channel may be formed by any suitable means known to the skilled artisan. In one or more embodiments, the reflective material 110 is sawed with a thin blade to create the channel between the PC-LEDs. Such opening and any corresponding light absorbing material therein may have a width, d3, in a range of from 20 μm to 50 μm. In some instances, the channels formed to a desired depth into the reflective material 110 such that the channel does not reach the solid tile support 102. Design of the channels and resulting light absorbing material depends on a desired application.

At operation 35, the channel is filled with light absorbing material. As shown in FIG. 7 and intermediate structure 100D, light absorbing material 114 is contained by the channel (112 of structure 100C of FIG. 6). In some embodiments, the reflective material 110 is a thin vertical layer of light absorbing material. Without intending to be bound by theory, it is thought that the presence of the light absorbing material in the reflective material 110 facilitates reduced optical crosstalk between the PC-LEDs. The light absorbing material may comprise any suitable material known to the skilled artisan, for example, one or more of: silicone, carbon, and a metal material.

Turning to FIG. 8 and intermediate structure 100E, at operation 40 of method 10, the reflective material 110 and the light absorbing material 114 and a portion of the transparent cover layer 105 are planarized or ground to remove a portion thereof, e.g., a thin layer, from a top surface of the intermediate structure 100D. The thin layer of the reflective material 110 and the light absorbing material 114 and the transparent cover layer 105 may be removed by any suitable means including, but not limited to chemical mechanical planarization (CMP) and grinding. Upon planarizing, the reflective material 110 yields a reflective coating 111, which may have any suitable thickness. In one or more embodiments, the reflective coating 111 has a thickness in a range of from 40 μm to 60 μm.

In one or more embodiments, the reflective coating 111 serves not only to reflect light, but also serves as a structure element of an array by holding the PC-LEDs 109x, 109y, and 109z of the array together in conjunction with the solid tile support 102. Thus, in one or more embodiments, the PC-LEDs 109x, 109y, and 109z in the light-emitting diode (LED) array are fixed in place by the reflective coating 111.

At optional operation 45 and with reference to FIG. 9, the array 100f is sawed to decrease the length of the solid tile support 102.

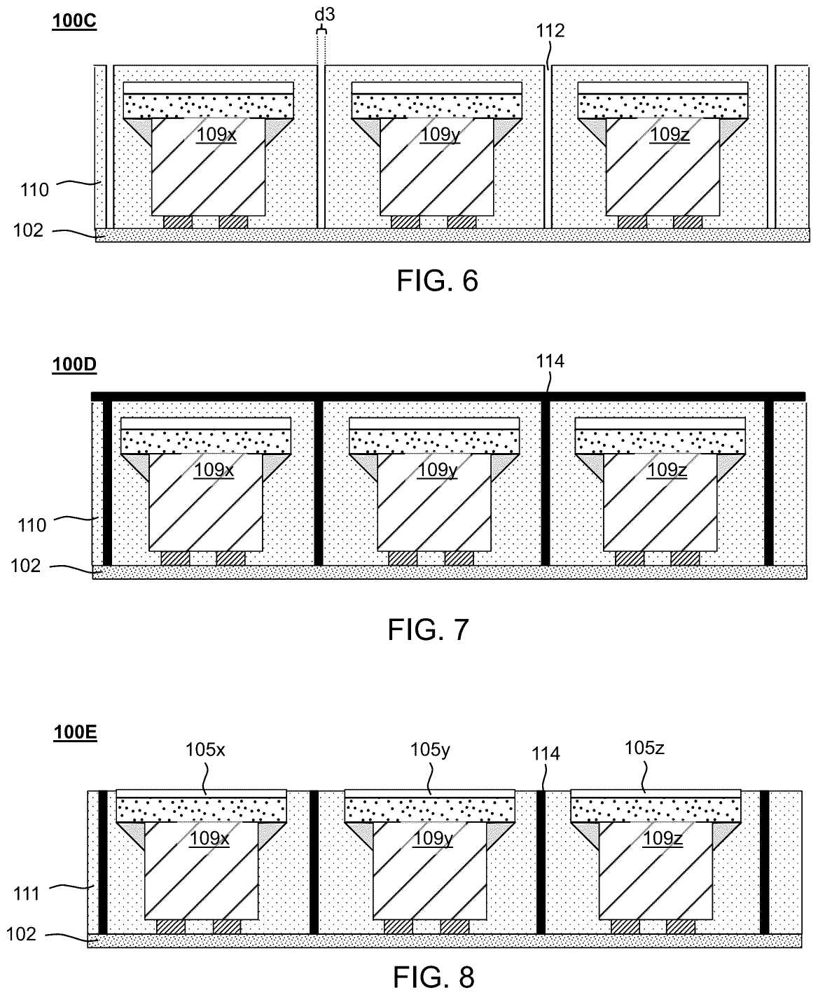

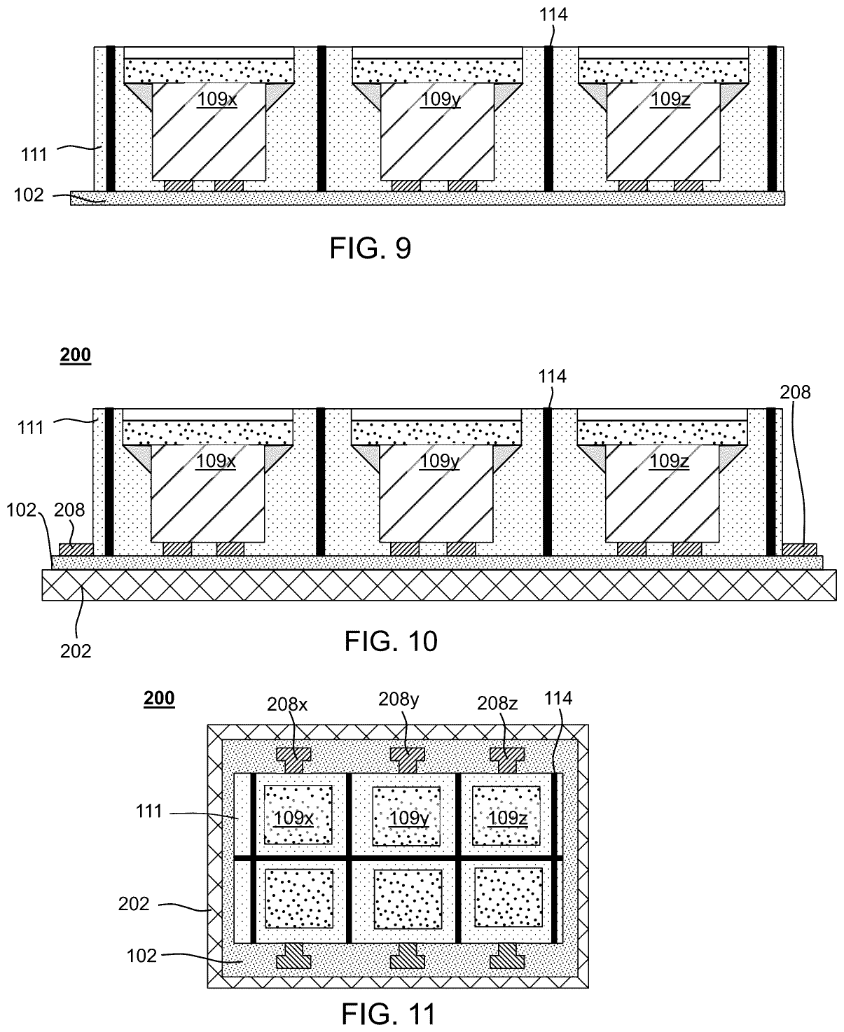

At operation 50 and with reference to one embodiment according to FIGS. 10-11, the array 100F of FIG. 9 is optionally affixed to a device substrate 202 to prepare a LED device 200. The device substrate 202, may be for example, a printed circuit board (PCB) or other suitable substrate for inclusion in a final system or device. Contacts 208 (specifically 208x, 208y, and 208z) associated with PC-LEDs 109x, 109y, 109z are deposited on the solid tile support 102.

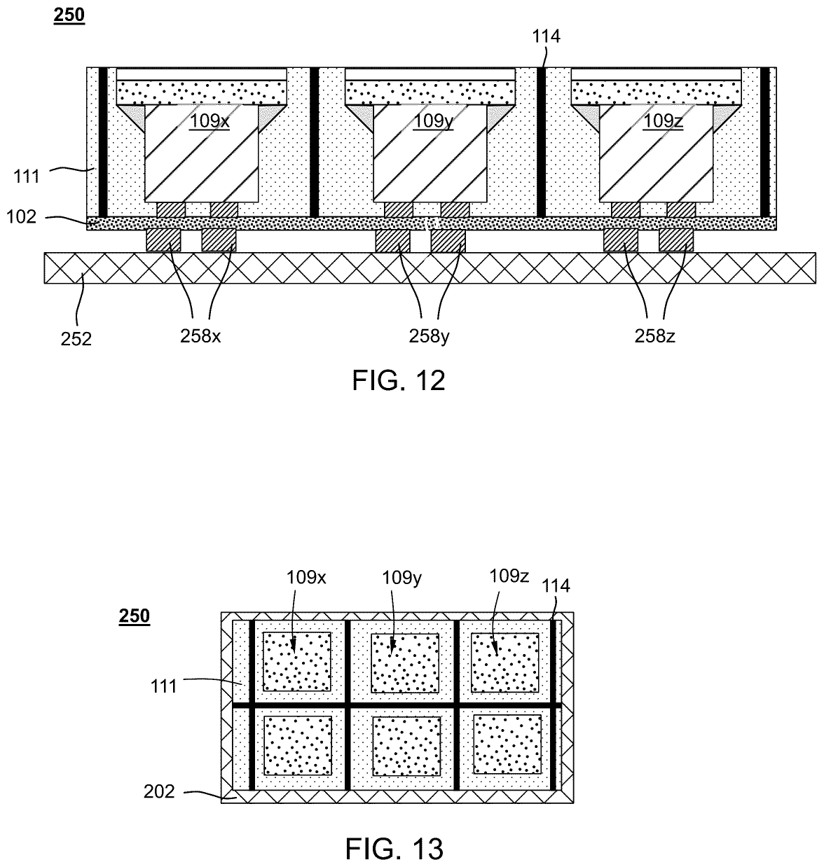

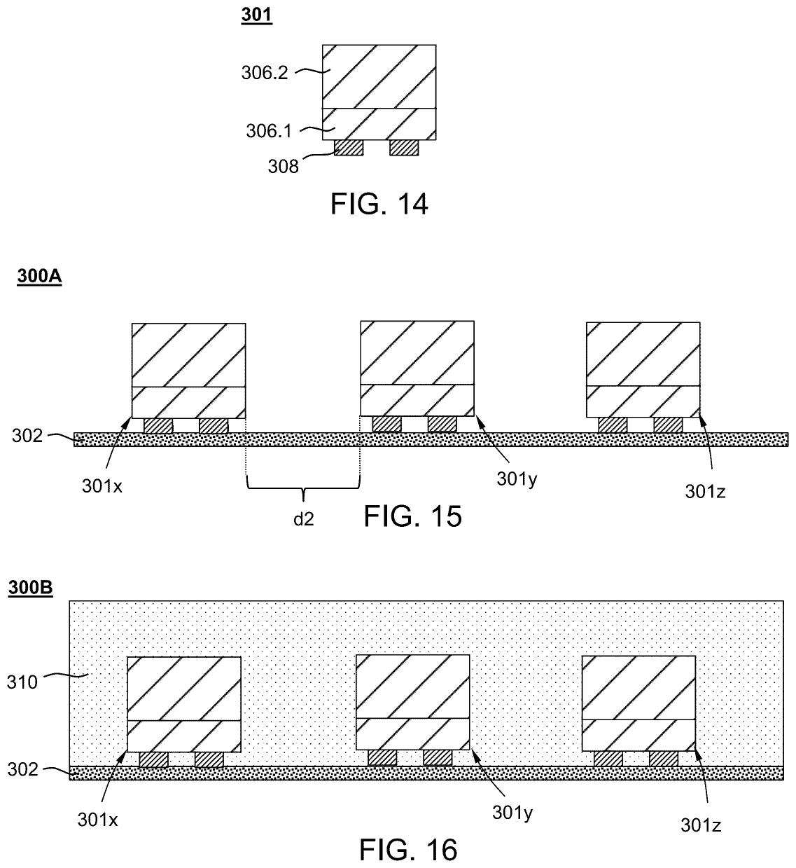

At operation 50 and with reference to FIGS. 12-13, the array 100F of FIG. 9 is affixed to a device substrate 252 having device contacts 258x, 258y, 258z to prepare a LED device 250. The device contacts 258x, 258y, and 258z are associated with PC-LED 109x, 109y, 109z. The device contacts 258x, 258y, and 258z are in a coplanar configuration relative to each other.

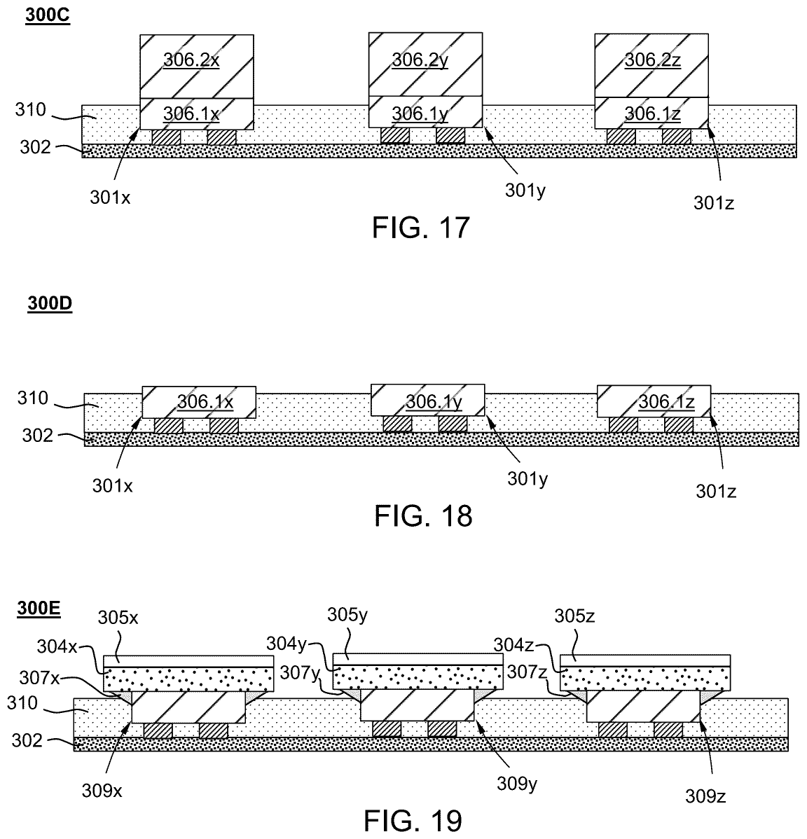

The following is with reference to FIG. 2 and FIGS. 14-24. FIGS. 14 to 24 illustrate views of LED intermediate structures/arrays 300A to 3001 during preparation of an LED device 200 following the process flow illustrated for method 50 of FIG. 2.

FIG. 2 depicts a flow diagram of a method 50 of manufacturing a light emitting device in accordance with one or more embodiments of the present disclosure. With reference to FIG. 2, in one or more embodiments, the method begins at operation 51 where light emitting diode (LED) die including semiconductor-containing structure and growth substrate are provided.

FIG. 14 illustrates a cross-sectional view of a light emitting diode (LED) die 301 according to one or more embodiments.

The LED die 301 comprises a growth substrate 306.2 and at least a stack of semiconductor layers 306.1 and at least one electrical contact, otherwise known as an underbump metallization (UBM) 308. For illustration purposes, two UBMs 308 are shown in FIG. 14. The LED die could further include internal bonding layers or other layers/features. For illustration purposes, the LED die 301 has a flip chip configuration. In one or more embodiments, the flip chip configuration is a thin film flip chip configuration (TFFC).

The UBM 308 may comprise any suitable contact known to the skilled artisan analogous to the UBM 108 of FIG. 3.

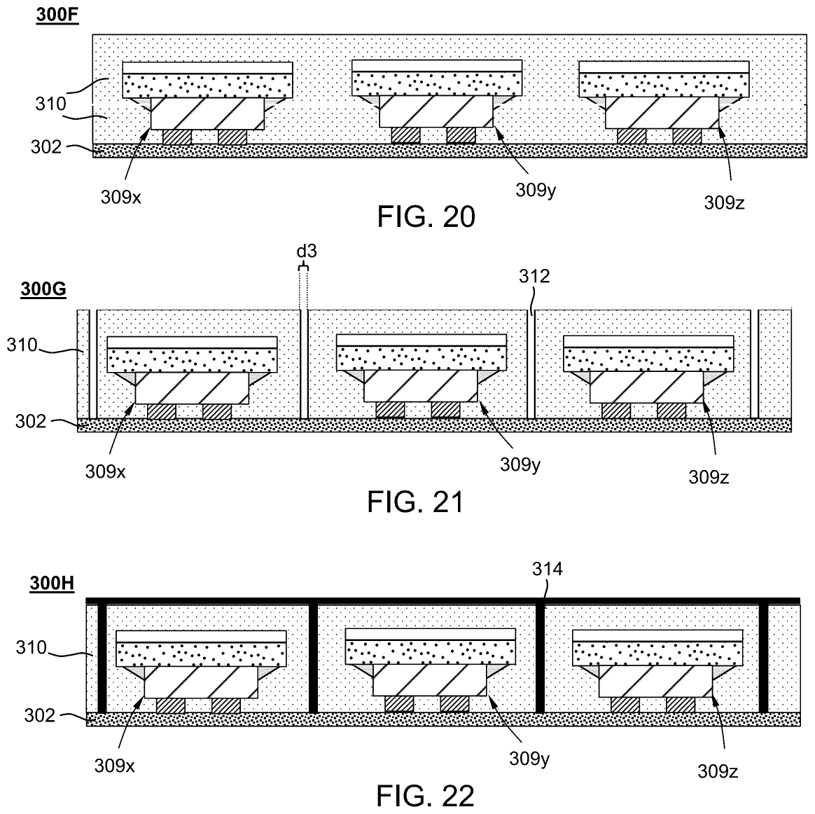

At operation 55 of FIG. 2, the LED die are assembled on a solid tile support in a spaced apart configuration. Assembling the LED die on the solid tile support at operation 55 of FIG. 2 yields intermediate LED structure 300A of FIG. 15, which comprises a plurality of LED die 301x, 301y, and 301z, which include respective features analogous to FIG. 14: growth substrate, at least a stack of semiconductor layers 306.1, and at least one UBM.

The LED die 301x, 301y, and 301z are assembled onto a surface of the solid tile support 302 by way of their respective UBMs. Distance “d2” is between adjacent stacks of semiconductor layers of the underlying die 301x, 301y, 301z. It is understood that an entire assembly of the various LED die 301x, 301y, and 301z from total number to arrangement of grids is done according to end-applications.

The solid tile support 302 is analogous to the solid tile support 102 of FIGS. 4-13.

Turning to FIG. 16 and intermediate structure 300B, at operation 60 of method 50, a (first) reflective material 310 is disposed around the LED die of the intermediate structure 300A. In one or more embodiments, the reflective material 110 is molded around the LED die. The reflective material 310 interacts with all surfaces of the LED die 301x, 301y, and 301z except for the UBM surfaces that are on the solid tile support 302. The reflective material 310 is analogous to the reflective material 110 discussed herein.

At operation 65 and with reference to FIG. 17, for intermediate structure 300C a portion of the reflective material 310 of intermediate structure 300B is removed to expose sides and tops of the respective growth substrates (306.2x, 306.2y, 306.2z), e.g., sapphire, and generally a portion of the underlying stacks of semiconductor layers (306.1x, 306.1y, 306.1z) of LED die (respectively 301x, 301y, and 301z).

At operation 70 and with reference to FIG. 18, the growth substrates are removed from intermediate structure 300C to yield intermediate structure 300D comprising the underlying stacks of semiconductor layers (306.1x, 306.1y, 306.1z) of LED die (respectively 301x, 301y, and 301z) and remaining reflective material 310.

At operation 75 and with reference to FIG. 19, in intermediate structure 300E a phosphor layer 304x, 304y, 304z is attached to respective underlying die 301z, 301y, 301z. A transparent cover layer 305x, 305y, 305z is thereafter deposited on the respective phosphor layer 304x, 304y, 304z. The intermediate structure 300E now includes PC-LEDs 309x, 309y, 309z.

Turning to FIG. 20, at operation 80, a (second) reflective material 310 is deposited around the PC-LEDs of the intermediate structure 300E to prepare intermediate structure 300F.

At operation 85, a channel is prepared in the reflective material 310 between the PC-LEDs. As shown in FIG. 21 and intermediate structure 300G, channel 312 extends into the reflective material 310 to a desired depth towards the solid tile support 302. In some instances, as illustrated, the channel 312 extends completely through the reflective material 310 to the solid tile support 302. The channel may be formed by any suitable means known to the skilled artisan. In one or more embodiments, the reflective material 310 is sawed with a thin blade to create the channel between the PC-LEDs. Such opening may have a width, d3, in a range of from 20 μm to 50 μm. In some instances, the channels are formed to a desired depth into the reflective material 210 such that the channel does not reach the solid tile support 302. Design of the channels and resulting light absorbing material depends on a desired application.

At operation 90, the channel is filled with light absorbing material. As shown in FIG. 22 and intermediate structure 300H, light absorbing material 314 is contained by channels (312 of structure 300G of FIG. 21). The reflective material 310 is analogous to reflective material 110.

Turning to FIG. 23 and array 3001, at operation 95 of method 50, the reflective material 310 and the light absorbing material 314 and the transparent cover layer 305 are planarized or ground to remove a portion thereof from a top surface of the intermediate structure 300H. The reflective material 310 and the light absorbing material 314 and the transparent cover layer 305 may be removed by any suitable means including, but not limited to chemical mechanical planarization (CMP) and grinding. Upon planarizing, the reflective material 310 yields a reflective coating 311, which may have any suitable thickness. In one or more embodiments, the reflective coating 311 has a thickness in a range of from 40 μm to 60 μm.

In one or more embodiments, the reflective coating 311 serves not only to reflect light, but also serves as a structure element of an array by holding the PC-LEDs 309x, 309y, and 309z of the array together in conjunction with the solid tile support 202. Thus, in one or more embodiments, the PC-LEDs 309x, 309y, and 309z in the light-emitting diode (LED) array are fixed in place by the reflective coating 311.

An optional operation, not illustrated, analogous to operation 45 of method 10 of FIG. 1, including sawing the array 3001 to decrease the length of the solid tile support 302.

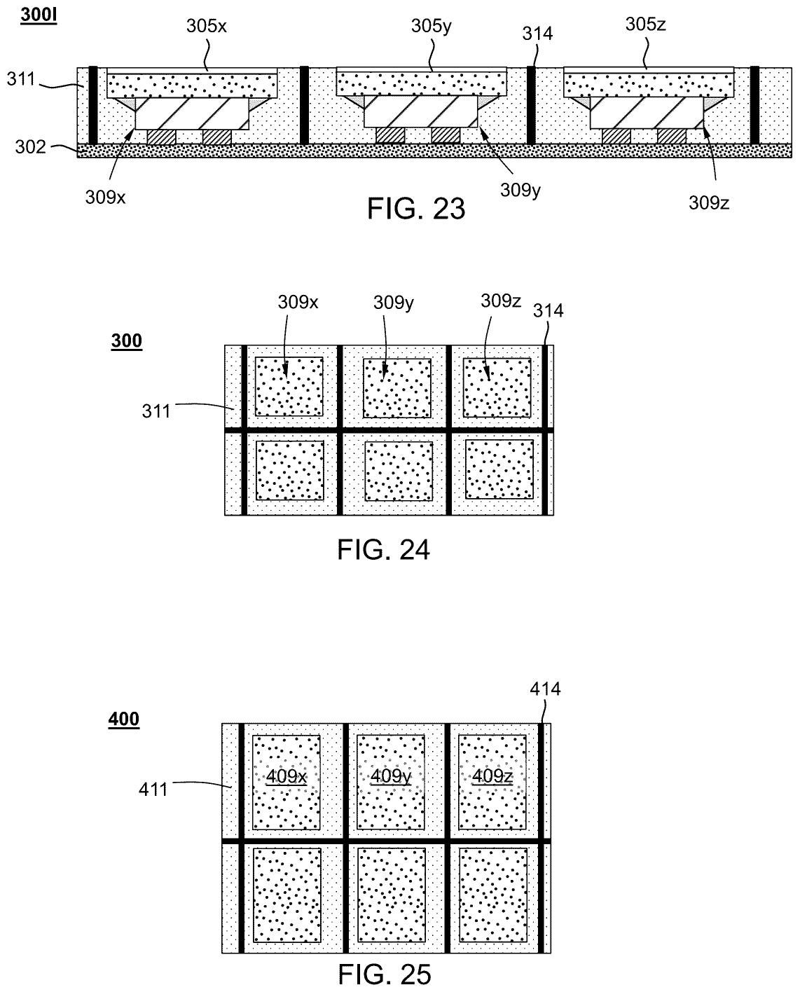

Optionally, at operation 99 and with reference to one embodiment according to FIGS. 23-24, the array 3001 or 300 is affixed to a device substrate to prepare a LED device 300. The device substrate, may be for example, a printed circuit board (PCB) or other suitable substrate for inclusion in a final system or device. In one or more embodiments, contacts of the device substrate correspond to UBMs of the PC-LEDs 309x, 309y, 309z.

Top plan view of array 300 of FIG. 24 shows PC-LEDs 309x, 309y, 309z fixed in place by reflective coating 311 and separated by light absorbing material 314.

FIGS. 25-26 illustrate top plan views of various LED arrays according to various embodiments. In FIG. 25, array 400 includes rectangular-shaped or configured die 409x, 409y, 409z which are held in place by reflective coating 411 and having light absorbing material 414 therebetween. Utilizing larger pixels of rectangular configurations in turn leads to fewer controls and switches. In FIG. 26, array 450 includes rectangular-shaped or configured die 409x, 409y, 409z which are held in place by reflective coating 411 and having light absorbing material 414 therebetween some but not all of the sides of the die. By placing the light absorbing material 414 between fewer than all of the sides of the die, larger pixel areas can be created, which in turn allow for additional efficiencies in end-use applications such as automotive headlamps.

### Applications

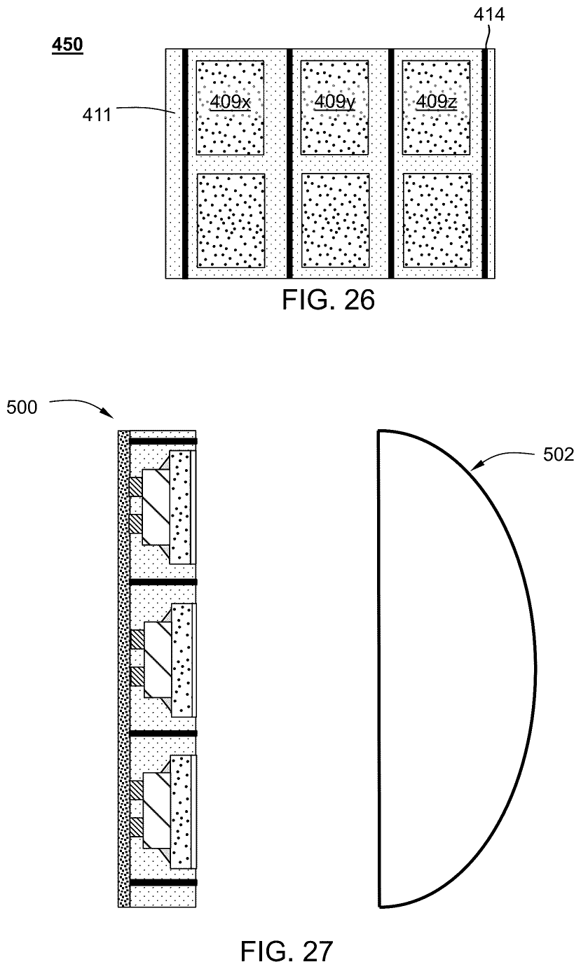

FIG. 27 shows a cross-section side view of a headlamp module according to one or more embodiments. LED array 500 according to any embodiment herein is placed in proximity to a headlamp lens 502.

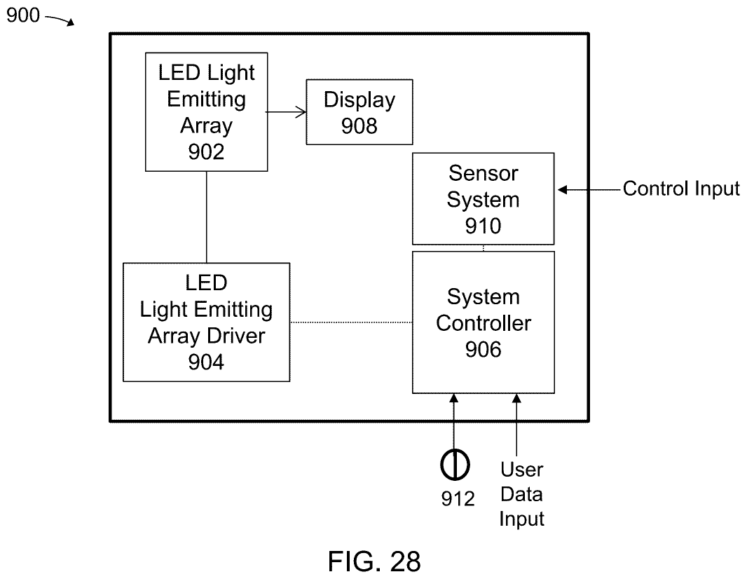

FIG. 28 schematically illustrates an exemplary LED system 900, e.g., a headlamp module system, utilizing LED arrays disclosed herein, for example the headlamp module of FIG. 25.

The LED system 900 comprises an LED light emitting array 902 and display 908 in electrical communication with an LED driver 904. The LED system 900 also comprises a system controller 906, such as a microprocessor. The controller 906 is coupled to the LED driver 904. The controller 906 may also be coupled to the display 908 and to optional sensor(s) 910, and be powered by power source 912. In one or more embodiments, user data input is provided to system controller 906.

In operation, illumination from some or all of the pixels of the LED array in 902 may be adjusted-deactivated, operated at full intensity, or operated at an intermediate intensity. Beam focus or steering of light emitted by the LED array in 902 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (I2C) serial bus, Serial Peripheral Interface (SPI), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor position.

### EMBODIMENTS

Various embodiments are listed below. It will be understood that the embodiments listed below may be combined with all aspects and other embodiments in accordance with the scope of the invention.

Embodiment (a). A light-emitting diode (LED) array comprising: a plurality of phosphor-converted light emitting diodes (PC-LEDs) arranged in a grid on a solid tile support; a reflective coating retaining the PC-LEDs in place; each of the PC-LEDs comprising: a die including an under bump metallization (UBM) affixing the PC-LED to a surface of the solid tile support; a phosphor layer affixed to a surface of the die opposite the UBM; and a transparent cover layer on the phosphor layer.

Embodiment (b). The LED array of embodiment (a), wherein each of the phosphor layers is separated from an adjacent phosphor layer by a first distance (d1) in a range of to 10 μm to less than or equal to 1000 μm, including greater than or equal to 50 μm to less than or equal to 100 μm.

Embodiment (c). The LED array of embodiment (a) or (b), wherein each of the phosphor layers has a width greater than a width of respective die to which it is affixed.

Embodiment (d). The LED array of embodiment (c), wherein the phosphor layers is affixed to the respective die with an adhesive layer that includes adhesive filets spanning from undersides of the phosphor layers to side surfaces of the respective die.

Embodiment (e). The LED array of any one of embodiments (a) to (d), wherein each of the die is separated from an adjacent die by a distance in a range of greater than or equal to 10 μm to less than 1000 μm, including greater than or equal to 120 μm to less than 500 μm.

Embodiment (f). The LED array of any one of embodiments (a) to (e) further comprising a layer of light absorbing material in a channel of the reflective coating.

Embodiment (g). The LED array of embodiment (f), wherein the light absorbing material comprises of one or more of silicone, carbon particles, or a metal material.

Embodiment (h). The LED array of embodiment (f), wherein a thickness of the light absorbing layer is greater than or equal to 1 μm to less than or equal to 1000 μm, including greater than or equal to 20 μm to less than or equal to 50 μm.

Embodiment (i). The LED array of embodiment (f), wherein the light absorbing material surrounds fewer than all sides of the die.

Embodiment (j). The LED array of embodiment 1, wherein each of the die comprises a vertical flip chip structure, optionally including a silicon substrate.

Embodiment (k). The LED array of any one of embodiments (a) to (j) wherein the solid tile support is an interposer, a printed circuit board (PCB), or a ceramic substrate.

Embodiment (I). The LED array of any one of embodiments (a) to (k), wherein the phosphor layer is a ceramic phosphor, a phosphor in glass, or a platelet of phosphor in silicone.

Embodiment (m). The LED array of any one of embodiments (a) to (I), wherein the UBMs comprise one or more of: copper (Cu), nickel (Ni), aluminum (AI), and gold (Au); and/or the reflective coating comprises a reflective material selected from the group consisting of: silicone, silicon dioxide (SiO₂), titanium oxide (TiO₂), zirconium oxide (ZrO₂), aluminum oxide (Al₂O₃), and combinations thereof; and/or the reflective coating has a reflectance in a range of from 80% to 99%; and/or the reflective coating has a thickness in a range of from greater than or equal to 10 μm to less than or equal to 500 μm.

Embodiment (n). The LED array of any one of embodiments (a) to (m), wherein the transparent cover layer comprises a glass; a sapphire; or a silicone material, optionally the silicone material further including titania (TiO₂) and/or silica (SiO₂).

Embodiment (o). The LED array of any one of embodiments (a) to (n), wherein the die have a rectangular configuration and/or a square configuration.

Embodiment (p). A headlamp module comprising the LED array of any one of embodiments (a) to (o), and a headlamp lens configured to receive light from the LED array.

Embodiment (q). A method of manufacturing a light-emitting diode (LED) array, the method comprising: attaching a plurality of phosphor-converted light-emitting diodes (PC-LEDs) including a transparent cover layer in a spaced apart configuration to a solid tile support; depositing a reflective material around the PC-LEDs; preparing a channel in the reflective material between the PC-LEDs; filling the channel with a light absorbing material in the channel; and planarizing by removing a thin layer of the reflective material, the light absorbing material, and the transparent cover layer to form the light-emitting diode (LED) array.

Embodiment (r). The method of embodiment (q), further comprising sawing the LED array, and/or soldering the LED array to a printed circuit board (PCB).

Embodiment (s). A method of manufacturing a light-emitting diode (LED) array, the method comprising: attaching a plurality of light-emitting diode (LED) die in a spaced apart configuration to a solid tile support; depositing a first reflective material around the die; removing a portion of the first reflective material to expose a growth substrate of each of the die; removing the growth substrate of each of the die; attaching a phosphor layer to each of the LED die, and a transparent cover layer on the phosphor layer to prepare phosphor-converted light-emitting diodes (PC-LEDs); depositing a second reflective material around the PC-LEDs; preparing a channel in the second and optionally first reflective materials between each of the PC-LEDs; filling the channel with a light absorbing material; and planarizing by removing a thin layer of the second and optionally first reflective materials and the light absorbing material and the transparent cover layer to form the light-emitting diode (LED) array.

Embodiment (t). The method of embodiment(s), further comprising sawing the LED array, and/or soldering the LED array to a printed circuit board (PCB).

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light-emitting diode (LED) array comprising:
a plurality of phosphor-converted light emitting diodes (PC-LEDs) arranged in a grid on a solid tile support;
a reflective coating surrounding each of the PC-LED in place;
each of the PC-LEDs comprising:
a die including an under bump metallization (UBM) affixing the PC-LED to a surface of the solid tile support;
a phosphor layer affixed to a surface of the die opposite the UBM; and
a transparent cover layer on the phosphor layer.

2. The LED array of claim 1, wherein each of the phosphor layers is separated from an adjacent phosphor layer by a first distance (d1) in a range of greater than or equal to 10 μm to less than or equal to 1000 μm.

3. The LED array of claim 1, wherein each of the phosphor layers has a width greater than a width of the respective die to which it is affixed.

4. The LED array of claim 3, wherein each of the phosphor layers is affixed to the respective die with an adhesive layer that includes adhesive filets spanning from undersides of the phosphor layers to side surfaces of the respective die.

5. The LED array of claim 1, wherein each of the dies is separated from an adjacent die by a second distance (d2) in a range of greater than or equal to 10 μm to less than 1000 μm.

6. The LED array of claim 1 further comprising a layer of light absorbing material in a channel of the reflective coating.

7. The LED array of claim 6, wherein the light absorbing material comprises of one or more of silicone, carbon particles, or a metal material.

8. The LED array of claim 6, wherein a thickness of the light absorbing layer is greater than or equal to 1 μm to less than or equal to 1000 μm.

9. The LED array of claim 6, wherein the light absorbing material surrounds fewer than all sides of the die.

10. The LED array of claim 1, wherein each of the die comprises a vertical flip chip structure, optionally including a silicon substrate.

11. The LED array of claim 1 wherein the solid tile support is an interposer, a printed circuit board (PCB), or a ceramic substrate.

12. The LED array of claim 1, wherein the phosphor layer is a ceramic phosphor, a phosphor in glass, or a platelet of phosphor in silicone.

13. The LED array of claim 1, wherein the UBMs comprise one or more of: copper (Cu), nickel (Ni), aluminum (Al), and gold (Au); and/or the reflective coating comprises a reflective material selected from the group consisting of: silicone, silicon dioxide (SiO₂), titanium oxide (TiO₂), zirconium oxide (ZrO₂), aluminum oxide (Al₂O₃), and combinations thereof; and/or the reflective coating has a reflectance in a range of from 80% to 99%; and/or the reflective coating has a thickness in a range of from greater than or equal to 10 μm to less than or equal to 500 μm.

14. The LED array of claim 1, wherein the transparent cover layer comprises a glass; or a sapphire; or a silicone material, optionally the silicone material further including titania (TiO₂) and/or silica (SiO₂).

15. The LED array of claim 1, wherein the die have a rectangular configuration and/or a square configuration.

16. A headlamp module comprising the LED array of claim 1, and a headlamp lens configured to receive light from the LED array.

17. A method of manufacturing a light-emitting diode (LED) array, the method comprising:
attaching a plurality of phosphor-converted light-emitting diodes (PC-LEDs) including a transparent cover layer in a spaced apart configuration to a solid tile support;
depositing a reflective material around the PC-LEDs;
preparing a channel in the reflective material between the PC-LEDs,
filling the channel with a light absorbing material;
planarizing by removing a thin layer of the reflective material, the light absorbing material, and the transparent cover layer to form the light-emitting diode (LED) array.

18. The method of claim 17, further comprising sawing the LED array, and/or soldering the LED array to a printed circuit board (PCB).

19. A method of manufacturing a light-emitting diode (LED) array, the method comprising:
attaching a plurality of light-emitting diode (LED) die in a spaced apart configuration to a solid tile support;
depositing a first reflective material around the die;
removing a portion of the first reflective material to expose a growth substrate of each of the die;
removing the growth substrate of each of the die;
attaching a phosphor layer to each of the LED die, and a transparent cover layer on the phosphor layer to prepare phosphor-converted light-emitting diodes (PC-LEDs);
depositing a second reflective material around the PC-LEDs;
preparing a channel in the second and optionally first reflective materials between each of the PC-LEDs, the channel extending into the second and optionally first reflective materials;
filling the channel with a light absorbing material; and
planarizing by removing a thin layer of the second and optionally first reflective materials, and the light absorbing material, and the transparent cover layer to form the light-emitting diode (LED) array.

20. The method of claim 19, further comprising sawing the LED array, and/or soldering the LED array to a printed circuit board (PCB).
